(19) United States
(12) Patent Application Publication
(10) Pub. No.: US 2013/0147511 A1
(43) Pub. Date: Jun. 13, 2013

(54) Offline Device Authentication and Anti-Counterfeiting Using Physically Unclonable Functions

(71) Applicants: Patrick Koeberl, Knocklyon (IE); Jiangtao Li, Beaverton, OR (US); Anand Rajan, Beaverton, OR (US); Claire Vishik, Austin, TX (US)

(72) Inventors: Patrick Koeberl, Knocklyon (IE); Jiangtao Li, Beaverton, OR (US); Anand Rajan, Beaverton, OR (US); Claire Vishik, Austin, TX (US)

(21) Appl. No.: 13/313,298

(22) Filed: Dec. 7, 2011

(51) Int. Cl. H03K 19/23

(52) U.S. Cl. 326/8

(57) ABSTRACT

The output of a physically unclonable function (PUF) may be processed to reduce its size. The post-processing result is served as a device intrinsic unclonable identifier and is signed by the device manufacturer to create a certificate stored on board the same device that includes the physically unclonable function. This scheme may not require online verification and complex error correction on PUFs in some cases.

### BACKGROUND

This relates generally to authenticating integrated circuits.

The contamination of electronic component supply chains by counterfeit hardware devices is a serious and growing risk in today's globalized marketplace. Re-marked devices account for the bulk of the counterfeits detected. In a typical re-marking attack, a device's product markings are misrepresented by replacing the original markings with markings indicating a higher specification and, hence, a more valuable part. Such a device, if embedded in an electronic system, may fail in the field when subjected to a different operational environment than the original part was designed for. The risk of counterfeit products entering the supply chain increases when devices suffer supply shortfalls or have production terminated by the manufacturer.

Current practice for detecting counterfeit semiconductors includes visual checking, electrical testing, and reliability testing which can require significant investments in expertise, equipment, and time. Such methods cannot guarantee the provenance or performance of a device and, in many cases, it may only be feasible to perform testing on a sample of devices, for example when tests are destructive. Standardized methods providing device traceability and authentication have been defined, however these are serialization mechanisms based on the generation of unpredictable, random codes and are intended to be applied at the device package and higher levels. They also require on-line access to secure manufacturer databases which may constrain their deployment in production facilities.

### BRIEF DESCRIPTION OF THE DRAWINGS

FIG. 1 is a schematic depiction of one embodiment of the present invention in the enrollment phase;

FIG. 2 is a schematic depiction of the present invention in the evaluation phase;

FIG. 3 is a flow chart for one embodiment;

FIG. 4 is a flow chart for another embodiment; and

FIG. 5 is a schematic depiction for one embodiment.

### DETAILED DESCRIPTION

A physically unclonable function-based device authentication scheme may be targeted at manufacturing environments in some embodiments. In one embodiment, a physically unclonable function-based authentication scheme removes the need for authentication to be performed on-line and for large and secure databases to be maintained, both of which are impediments to adoption. For a reasonable cost, in terms of on-chip storage and computational expense at the verifier, a level of security can be achieved that is sufficient to raise the effort for the attacker to uneconomic levels. In some embodiments, a scheme may be integrated into the manufacturing context by leveraging existing test methodologies and standards.

A physically unclonable function or PUF is a physical system that, when measured or challenged, provides unique, repeatable and unpredictable responses. Creating a physical copy of the PUF with an identical challenge-response behavior is hard, resulting in a structure which is unclonable even by the manufacturer.

Silicon PUFS exploit the uncontrollable manufacturing variations that are a result of integrated circuit fabrication processes. Manufacturing variation of parameters, such as dopant concentrations and line widths, manifest themselves as differences in timing behavior between instances of the same integrated circuit design. These timing differences can be measured using a suitable circuit.

An arbiter PUF compares the relative delay of two delay paths using a series of configurable delay elements terminated by an arbiter. By using a PUF challenge as the delay element configuration vector, the circuit exhibits a challenge space which is exponential in the number of challenge bits.

A ring oscillator PUF compares the relative frequencies of self-oscillating delay loops in order to generate PUF responses. A single response bit can thus be generated by a pair of oscillators.

Another PUF type is based on the power-up state of uninitialized six-transistor SRAM cells. The storage mechanism in an SRAM cell consists of four cross-coupled transistors that assume one of two stable states after power-up. Which state the cell enters is largely determined by the relative characteristics of the transistors, so any mismatch causes the cell to have a bias to one of the states. The mismatch is fixed at manufacturing time, resulting in a cell that tends to power up in the same state. The power-up behavior is random between cells, but robust for a single cell, resulting in a structure that is well suited for use as a PUF. The challenge in the case of an SRAM PUF can be considered to be a set of SRAM addresses, and the response the contents of those addresses post power-up.

A (m, δ) family of single-challenge physically unclonable functions is a set of probabilistic algorithms with the following procedures.

The output of the instantiation procedure is a PUF with a unique identity id_{PUF} ∈{0, 1}^{m}. Given a physically unclonable function PUF, the evaluation procedure on each query results in a noisy identity id_{PUF} β e where e ∈{0, 1}^{m} is a random noise vector with a Hamming distance of δ or less.

The unclonability property of a single-challenge PUF may be defined as follows: A PUF is unclonable is there exists no efficient clone procedure that gets n PUF devices D₁, . . . ,Dₙ and builds another physical PUF device D′ such that the Hamming distance between the identities id_{Di} and id_{D}, is less than 2δ for any i=1, . . . , n.

In some embodiments, an offline device authentication scheme can be implemented using a PUF. The scheme may make use of a digital signature scheme (Sign, Verify) and a family of single-challenge PUFs (m, δ)-PUF. Let (mpk, msk) be the device manufacturer's verification key and private signing key pair. In an enrollment phase, each device is certified by the hardware manufacturer. In the evaluation phase, the hardware device is verified by a verifier who received the device from the supply chain.

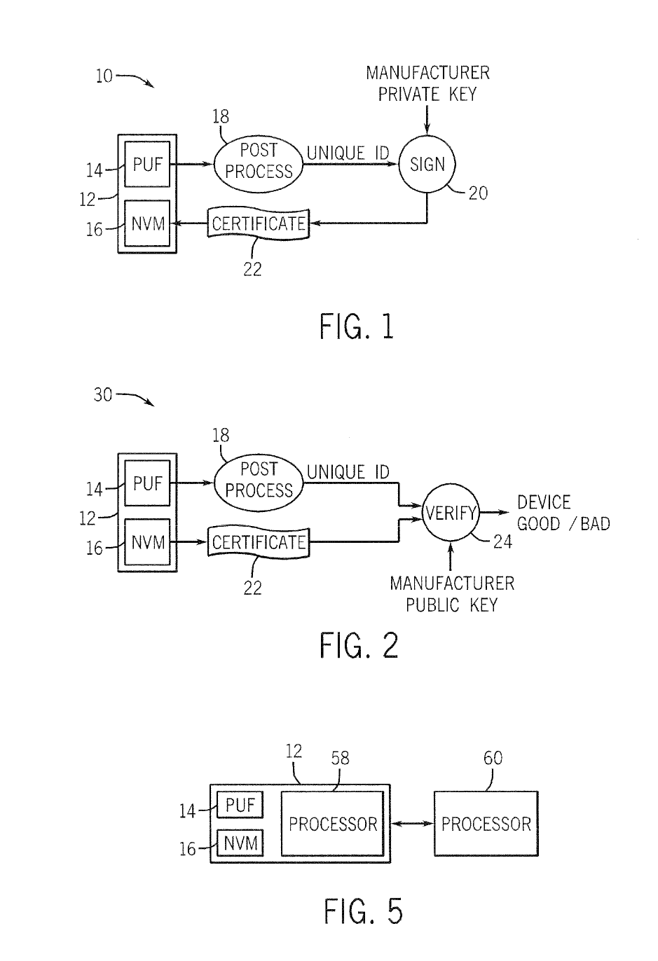

Referring to FIG. 1, the enrollment phase involves a hardware device certified by the manufacturer using the following steps. The manufacturer integrates a PUF 14 into the device 12. Then the manufacturer runs an evaluation procedure EVAL on PUF and obtains the unique identifier id_{PUF} from post-processing 18. Next the manufacturer uses msk to sign id_{PUF} at 20 and creates the signature e=sign_{MSK} (id_{PUF}). The manufacturer then sets the device certificate 22 as (id_{PUF}, e) and stores the certificate in a non-volatile memory and (NVM) 16 of the device 12.

Referring to FIG. 2, once the verifier obtains the hardware device 12 from the supply chain, the device can be verified by the following steps. The verifier runs the evaluation procedure EVAL of the PUF 14 in the device 12 and obtains id′ after post-processing 18. The verifier reads the device certificate 22 (id_{PUF}, σ) from the non-volatile memory 16 of the device 12. Then the verifier uses the mpk to verify the signature σ on id_{PUF} at 24. If the verification fails, the verifier rejects the device.

In some embodiments, the procedure may be repeated a fixed number of times and if the device fails in every one of those cases, the device may be rejected. The verifier checks that the Hamming distance between id_{PUF} and id′ is at most δ. If the Hamming distance is greater than δ, the verifier may reject the device, depending on how many times the test has been repeated. The verifier accepts the device if the steps succeed.

In some embodiments, no post-processing function 18 is needed for the basic authentication scheme. It is reserved for the full device authentication scheme described hereinafter. One can choose the following or other parameters. Let m equal 256. The output of the PUF then is a 256 bit value. Let (Sign, Verify) be an EC-DSA signature algorithm on a 256 bit prime elliptic curve. Federal Information Processing Standard 186-3 Digital Signature Standard (DSS). The signature is only 512 bits in size. The size of the device certificate then is 768 bits, in one embodiment. The manufacturer can store the device certificate on the device, such as in flash or fuses on the device, without a whole lot of overhead.

In some embodiments, device data such as device type, speed grade, model number, configuration, size of its non-volatile memory, and/or device features may be included in the device certificate. The verifier has to not only evaluate the PUF and verify the signature but also verify the device data in the device certificate. This addresses the device remarking attack.

A basic authentication scheme may be simple and inexpensive to implement. It may not require any on-line database access during the evaluation phase. The additional non-volatile storage required for the device may be small, in some embodiments, and, thus, a cost selective solution may be implemented. Unlike many PUF applications, the PUF queries and device certificates can be public and do not need to be protected in some embodiments. Error correction or fuzzy extractors may not be needed in some embodiments.

The PUF authentication scheme may be subject to a simulation attack. In such an attack, the attacker obtains a valid device from the manufacturer and reads out the device certificate. When the attacker counterfeits a new device, the attacker copies the device certificate into the non-volatile memory of the new device. Then the attacker embeds a PUF simulator in the integrated circuit such that if the verifier queries the PUF of the new device, the simulator always outputs id instead of the result from the actual PUF.

This counterfeit device can be successfully authenticated if the verifier cannot distinguish whether the PUF evaluation comes from a real PUF or a PUF simulator, PUF size may play a role in mitigating such an attack. Since such an attacker must be capable of reengineering the device to include a PUF simulator at the silicon level, it is the technological barrier, rather than the PUF size, that is likely to sway the device re-marketer, who is typically economically motivated. For attackers with other motivations, who are likely to be well funded, the PUF size may not be a sufficient deterrent. Nonetheless, since SRAM is a common primitive in devices, all or a portion of the SRAM can be used as a PUF for supply chain authentication purposes in some embodiments.

For example, the same basic authentication scheme can be used with m=2¹⁸. Then, in order to simulate the PUF, the attacker must embed 256 k bits of information in the device. One drawback of this approach is the size of the device certificate now becomes very large and, thus, the amount of non-volatile storage on the device required to store the certificate is also large. Of course, external storage could be used to store the device certificates, such as a hard disk or other on-line database.

Thus, a full device authentication scheme may be advantageous in mitigating against the hardware PUF simulation attack, while not increasing the amount of volatile memory requirements in some embodiments.

The m-bit identity of the PUF (for example, 256-kbit) may be compressed into a k-bit device ID (for example, 256-bits). The device ID and the corresponding signature. together become the device certificate. In this way, the device certificate is small enough to fit into the non-volatile storage 16 (FIG. 1) of the device 12 (FIG. 1). The compression or post-processing function 18, shown in FIGS. 1 and 2, may be designed to be noise preserving, in some embodiments.

In some embodiments, an (m,p)-family of Static Random Access Memory (SRAM) based PUFs are a set of probabilistic algorithms with two procedures. The instantiate procedure instantiates m physical SRAM cells S₁, . . . ,Sₘ, each storing an element from {0,1}. The ideal noise-free power-up state sᵢ of the SRAM cell Sᵢ is fixed for a specific instantiation, but independently and uniformly distributed over {0,1}.

The evaluate procedure on each query outputs a noisy power-up state \tilde{s}=\tilde{s}₁. . . \tilde{s}ₘ, where \tilde{s}ᵢ=sᵢ⊕e, with e a Bernoulli distributed random variable with probability p. Note that e is drawn independently for every SRAM cell at each evaluation.

A full device authentication scheme may use a digital signature scheme (Sign, Verify) and a family of SRAM (m,p)-PUFs. Let (mpk,msk) be the device manufacturer's public verification key and private signing key pair. Let Extract: {0,1}^{m}→{0,1}^{k} be the post-processing function that extracts m-bit SRAM PUF evaluation results into a k-bit device ID.

In some embodiments, a sequence 40 may be implemented in hardware, software, and/or firmware. In software and firmware embodiments, it may be implemented by computer executed instructions stored in one or more non-transitory computer readable media, such as a magnetic, optical, or semiconductor storage.

Then the device authentication scheme, in one embodiment, as be as follows:

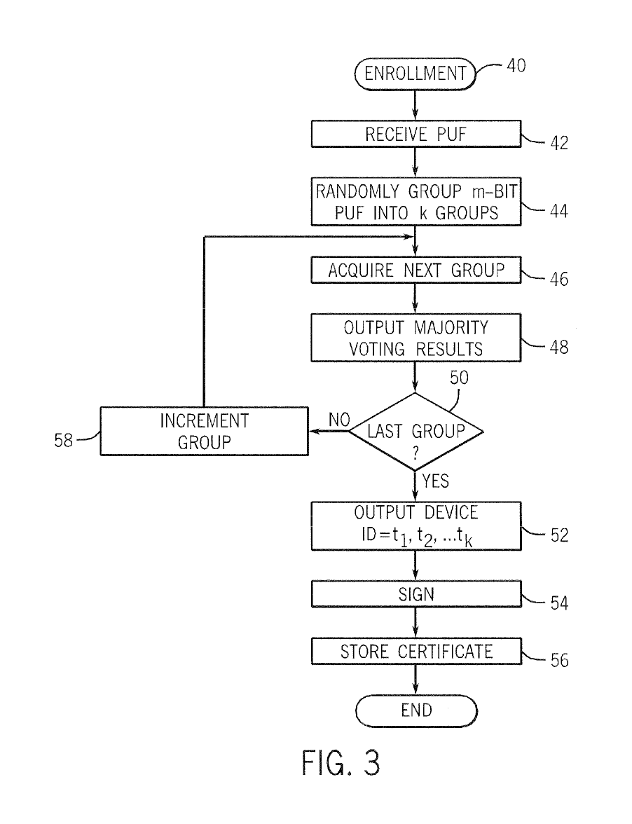

In the enrollment phase, a hardware device D is certified by the manufacturer. To do this, the manufacturer instantiates an SRAM PUF into the device in one embodiment, as shown in FIG. 3 at block 42. Then the manufacturer runs the evaluation procedure Eval and obtains the unique identity \tilde{s}. Next, the manufacturer runs the post-processing function to compute the device ID id_{D}=Extract(\tilde{s}) Then the manufacturer uses msk to sign id_{D} and create a signature a σ=Signₘₛₖ(id_{D}). Finally, the manufacturer sets the device certificate as (id_{D},σ) and stores the certificate in the non-volatile memory of the device. Then, in the evaluation phase, once a verifier obtains a hardware device from the supply chain, the verifier can verify the device with the following steps.

First, the verifier runs an evaluation of the SRAM PUF in the device and outputs \tilde{s}′=\tilde{s}′₁ . . . \tilde{s}′ₘ as the PUF evaluation result. In one embodiment, the verifier may use a random access to evaluate PUF as follows. The verifier chooses a random permutation of (i₁, . . . iₘ) of (1, . . . , m). Next the verifier queries the SRAM cells using the following order: Sᵢ_{₁}, . . . ,Sᵢ_{ₘ} and obtains \tilde{s}′ᵢ_{₁}, . . . , \tilde{s}′ᵢ_{ₘ}. Finally, the verifier outputs \tilde{s}′=\tilde{s}′₁. . . \tilde{s}′ₘ as the PUF evaluation result.

Then the verifier computes id′_{D}=Extract(\tilde{s}′). Next, the verifier reads (id_{D},σ) from the non-volatile memory of the device. Thereafter, the verifier uses the mpk to verify the signature σ on the id_{D}. If the verification fails, the verifier rejects the device. The verifier can also check that the Hamming distance between id_{D} and id′_{D} is at most δ, where δ is a security parameter. If the Hamming distance is great than δ, the verifier rejects the device. Finally, the verifier accepts the device if all the above steps succeed.

In some embodiments, the post-processing function 18 of FIGS. 1 and 2 may be implemented in hardware, software, and/or firmware. In software and firmware embodiments, the function may be implemented in one or more non-transitory computer executed media, such as semiconductor, magnetic, or optical storage.

Turning next to the post-processing function, the input to this function may be an in-bit string s=s₁ . . . sₘ (FIG. 3, block 42). If the output is the k-bit string t=t₁ . . . tₖ, m bits of s can be divided into k different groups (blocks 44, 46). Then, for each group (block 58), majority voting is performed (block 48) to output a single bit. After the last group (diamond 50), the resulting k bits from k groups is the output of the post-processing function (block 52). After signing with the msk (block 54), the certificate is stored (block 56).

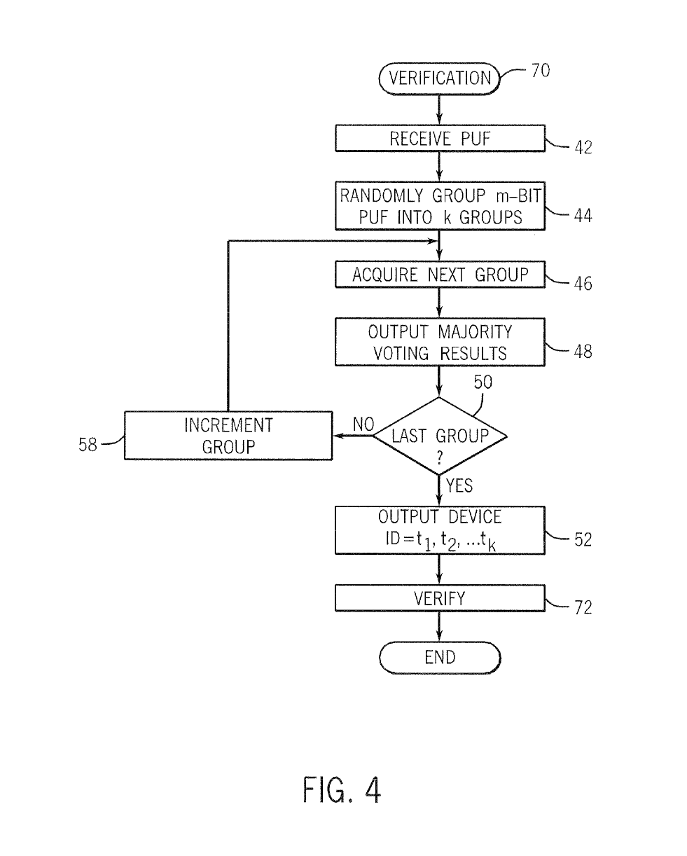

The verification sequence 70 of FIG. 4 may be implemented in firmware, software, and/or hardware. In software and firmware embodiments, it may be implemented by computer executed instructions stored in a non-transitory computer readable medium, such as a magnetic, semiconductor, or optical storage.

The verification sequence 70 may use the basic post-processing sequence including the steps 42-52 and 58, already described in connection with FIG. 3. Then the verification may be done in block 72 using the post-processing result and the storage certificate from the non-volatile memory 16, together with the manufacturer's public key, in order to determine whether the device is authentic or not, as indicated in block 72.

Thus, let l be the largest odd number, such that k·l≦m. Then, divide the first k·l bits of string s into k groups G₁, . . . , Gₖ, where each group has l bits. For each group Gᵢ, where 1≦i≦k, compute tᵢ=Voting(Gᵢ), the majority voting result of bits in Gᵢ. More specifically, let G={b₁, . . . , bₗ} where b₁, . . . , bₗ ∈ {0,1}. The majority voting function Voting(G) is then: Voting(G) outputs 1 if b₁+ . . . + b_{l>l/}2 and outputs 0 otherwise.

In one embodiment, the post-processing function can be as follows:

1. Let d be a small integer, a parameter to this function.

2. Let l be the largest odd number such that k·l·d≦m.

3. Divide the first k·l·d bits of string s into k groups G₁, . . . , Gₖ, where each group has l·d bits. The mapping from bits in s to k groups is random but fixed per function and is encoded in the algorithm.

4. For each group Gᵢ, where 1≦i≦k, compress l·d bits into an l-bit group G′ᵢ using the XOR operation as follows. Let G={b₀,b₁, . . . , b_{l·d-1}}. G′={c₀,c₁, . . . , cₗ₋₁} is computed by setting cⱼ=b_{d·j} ⊕ b_{d·j+1} ⊕. . . ⊕ b_{d·j+d-1}, for j=0, . . . , l−1.

5. For each group G′ᵢ, where 1≦i≦k,t₁=Voting (G′ᵢ), the majority voting result of bits in G′ᵢ. The final output of ƒ₂ is t₁,t₂, . . . tₖ.

The random PUF evaluation in the device evaluation phase and the random mapping from bits to groups in the post-processing function are used to defend against a PUF simulation attack using less than m-bit storage. The mapping from bits to groups is random, but fixed per function is encoded in the algorithm. The mapping can be public. The security of the device authentication scheme does not need to rely on the secrecy of the function, in some embodiments.

Some embodiments may be deployed in an electronic manufacturing environment, or they may be used to authenticate populated devices from different manufacturers as part of a production test regime. For devices already embodying SRAM and non-volatile memory, the cost imposed can be low when standards such as JTAG Test Access Port are used for SRAM PUF and non-volatile memory access. See 1149.1-1990-IEEE Standard Test Access Port and Boundary Scan Architecture.

The storage requirements of the device certificate are relatively modest, in some embodiments, on the order of 10³ bits when augmenting data, such as the device model number and speed grade, are added. For devices already embedding non-volatile memory, this requirement may be met by spare capacity. In the case where no non-volatile memory is available for certificate storage, it may be possible to store the certificate on the device package. Matrix codes are ideally suited here, although the integrated circuit package dimensions will in practice constrain how much data can be encoded.

In some embodiments, a re-marker wishing to clone the PUF must in effect re-engineer the device to include a PUF simulator at the silicon level. The cost of doing so is likely to outweigh the potential gain.

In some embodiments, the sequences shown in FIGS. 3 and 4 may be implemented in hardware. That hardware may be resident on the same integrated circuit 12 with the physically unclonable function 14 and non-volatile memory 16, as indicated by the processor 58 in FIG. 5. In other embodiments, a processor for implementing some or all of the sequences shown in FIGS. 3 and 4 may be implemented by an external processor 60, as indicated in FIG. 5 as well. For example, a manufacturer may have a programmer that includes the processor 60 and which implements the enrollment sequence shown in FIG. 1, for example.

Thus, embodiments of the present invention contemplate both situations where the integrated circuit, including the physically unclonable function, includes the processing hardware for implementing both the enrollment and authentication sequences. In other embodiments, one or more of these functions may be split between an internal processor and an external processor. In other embodiments, these functions may be implemented wholly internally to the same integrated circuit, including the physically unclonable function or wholly external thereto.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method of device authentication using a physically unclonable function comprising:
generating a device certificate based on a result of the physically unclonable function; and
storing the certificate on said device.

2. The method of claim 1 including storing the certificate on a device having the physically unclonable function.

3. The method of claim 1 including reducing the signed certificate by randomly grouping the physically unclonable function into a plurality of groups.

4. The method of claim 3 including using majority voting to reduce each group.

5. A method comprising:
processing the output of a physically unclonable function to reduce a signed certificate derived from the output; and
verifying the device by validating the certificate.

6. The method of claim 5 including signing the output with a private key to produce the certificate.

7. The method of claim 5 including reducing the signed certificate by randomly grouping the physically unclonable function into a plurality of groups

8. The method of claim 7 including using majority voting to reduce each group.

9. At least one non-transitory computer readable medium storing instructions that enable a computer to:
generate a device certificate based on a result of a physically unclonable function;
store the certificate; and
authenticate a device using said certificate.

10. The medium of claim 9 further storing instructions to store the certificate on a device having the physically unclonable function.

11. The medium of claim 9 further storing instructions to reduce the signed certificate.

12. The medium of claim 11 further storing instructions to reduce the signed certificate by randomly grouping the physically unclonable function into a plurality of groups.

13. The medium of claim 12 further storing instructions to use majority voting to reduce each group.

14. An apparatus comprising:
an integrated circuit, said integrated circuit including a physically unclonable function;
a non-volatile memory on said integrated circuit, said non-volatile memory to store a device certificate; and
a processor to generate the device certificate based on a result from the physically unclonable function and to store the certificate in said memory.

15. The apparatus of claim 14 wherein said processor is integrated in said integrated circuit.

16. The apparatus of claim 14 wherein said processor is external to said integrated circuit.

17. The apparatus of claim 14 including a unit to process the output of the physically unclonable function to reduce the signed certificate derived from the output and to verify the apparatus by validating the certificate.

18. The apparatus of claim 17 wherein said unit is part of said processor.

19. The apparatus of claim 17, said unit to store the certificate on the apparatus.

20. The apparatus of claim 19, said unit to reduce the signed certificate.

21. The apparatus of claim 20, said unit to reduce the signed certificate by randomly grouping the physically unclonable function into a plurality of groups.

22. The apparatus of claim 21, said unit to use majority voting to reduce each group.
